(19) United States
(12) Patent Application Publication
(10) Pub. No.: US 2022/0019886 A1
(43) Pub. Date: Jan. 20, 2022

(54) COMPUTER-IMPLEMENTED BOND NETWORK SYSTEM FOR POSTHUMOUS PERSONA SIMULATION

(71) Applicants: Justin Harrison, Woodland Hills, CA (US); Daniel Whitaker, Duvall, WA (US)

(72) Inventors: Justin Harrison, Woodland Hills, CA (US); Daniel Whitaker, Duvall, WA (US)

(21) Appl. No.: 16/928,392

(22) Filed: Jul. 14, 2020

(51) Int. Cl. G06N 3/08; G06F 30/20

(52) U.S. Cl. CPC G06N 3/08; G06Q 50/01; G06F 30/20

(57) ABSTRACT

A computer-implemented bond network platform has a processor. Further, the computer-implemented bond network platform has a bond network application server that generates, via a bond network-specific processor, a user interface for communications between a plurality of members of the bond network, captures, via the bond network-specific processor, data pertaining to one or more real-world interactions between a first member of the bond network and a plurality of subset member groups within the bond network, and generates, via the bond network-specific processor. The user interface posthumously simulates one or more communications from the first member to one of the plurality of subset member groups during lives of members of the plurality of subset member groups. Additionally, the computer-implemented bond network platform has an essence generation platform that generates, via a baseline essence generation engine during a life of the first member, a baseline virtual persona model of the human user.

### BACKGROUND

### 1. Field

This disclosure generally relates to the field of computing systems. More particularly, the disclosure relates to artificial intelligence (“AI”) systems.

### 2. General Background

With recent advances in computing ability, a variety of configurations have attempted to remove the need for human-to-human interactivity in favor of human-to-AI interactivity, specifically with respect to business transactions. For example, a variety of business-related software applications (e.g., banking, insurance, e-commerce, etc.) allow a user operating a computing device (e.g., desktop computer, laptop computer, smartphone, tablet device, smartwatch, etc.) to interact with a chatbot, which is generally deemed to be a software application operated by an AI. A human user may ask the chatbot various questions, which may be general in nature, account specific, product specific, service specific, etc.; subsequently, the chatbot may respond with an answer to that question. The dialogue between the human user and the chatbot typically takes the form of a text-based dialogue.

Even though the responsiveness of the chatbot may be as fast, or even faster, than that of a human agent, it often is limited in the interaction it can provide to a human user. For example, a user may have a question that is atypical of what most other users ask, and for which the chatbot does not have any answer; in such an instance, the chatbot may transition the dialogue to a human agent that can interact better with the human user.

Although some current chatbot configurations may be convincing enough to pass the Turing test (an evaluation to determine whether or not the chatbot's behavior is indistinguishable from that of a human being) in certain circumstances, as noted above, they are for the most part convincing because they simulate a stranger to that of the user. In other words, a user having a text-based dialogue with an agent about the user's account has no baseline of comparison other than how a human agent would answer account-specific questions. And even in those instances, a human agent often reads from an introductory script and provides standardized information. In other words, in a business-related dialogue, a chatbot may be able to simulate, with some degree of efficacy, the behavior of a customer service agent that is most likely a stranger to the user.

However, in more personal settings outside of the foregoing customer service contexts, current chatbots are easily identified by a human user. The reason for this is that personal interactions typically go beyond fact-based questions and answers. As much as current chatbot configurations may attempt to use colloquial phrases and verbiage, their behavior during an interaction with a human user is essentially limited to simulating interaction with a stranger.

As a result, current AI configurations are only able to simulate a generic version of a human's personality, and do so with realism that is limited to specific contexts and a minute level of functionality.

### SUMMARY

In one embodiment, a computer-implemented bond network platform has a processor. Further, the computer-implemented bond network platform has a bond network application server that generates, via a bond network-specific processor, a user interface for communications between a plurality of members of the bond network, captures, via the bond network-specific processor, data pertaining to one or more real-world interactions between a first member of the bond network and a plurality of subset member groups within the bond network, and generates, via the bond network-specific processor, the user interface posthumously simulates one or more communications from the first member to one of the plurality of subset member groups during lives of members of the plurality of subset member groups.

Additionally, the computer-implemented bond network platform has an essence generation platform that generates, via a baseline essence generation engine during a life of the first member, a baseline virtual persona model of the human user, dynamically modifies, via a dynamic essence generation engine, the baseline virtual persona model based on the one or more one or more real-world interactions between the first member and said one of the plurality of subset member groups during lives of members of the plurality of subset member groups, and posthumously simulates, via a neural network, a virtual persona of the first member based on the modified baseline virtual persona model.

In another embodiment, a computer program product comprises a non-transitory computer useable storage device having a computer readable program. When executed on a server computer, the computer readable program causes the server computer to perform the functionality of the computer-implemented bond network platform.

### BRIEF DESCRIPTION OF THE DRAWINGS

The above-mentioned features of the present disclosure will become more apparent with reference to the following description taken in conjunction with the accompanying drawings wherein like reference numerals denote like elements and in which:

FIG. 1 illustrates a computer-implemented bond network system that may be utilized to operate a software configuration that facilitates communication between members of a bond network while all of the members are alive, as well as posthumous simulations of personas of bond members after they are deceased.

FIG. 2A illustrates a smartphone operated by a user to invoke a messaging app to communicate with other bond network members. In one embodiment, the bond network user interface illustrates imagery (e.g., bond network member avatars) associated with the bond network.

FIG. 2B illustrates the user selecting a subset member group from the bond network user interface.

FIG. 2C illustrates an example of a text-based group subset communication between the bond network members selected via the bond network user interface.

FIG. 2D illustrates an example of a video-based group subset communication between the bond network members selected via the bond network user interface.

FIG. 3A illustrates an interaction data set that includes the bond network member, the affected member, and only one other bond network member.

FIG. 3B illustrates an interaction data set that includes the bond network member, the affected member, and two other bond network members.

FIG. 4A illustrates a system configuration for the bond network application server, illustrated in FIG. 1.

FIG. 4B illustrates a system configuration for the essence generation platform illustrated in FIG. 1.

FIG. 5 illustrates a computer-implemented process that may be utilized to generate a bond network for posthumous persona simulation.

### DETAILED DESCRIPTION

A computer-implemented bond network system provides for a software configuration (e.g., software application such as an “app”) that allows members of a bond network to communicate with each other, irrespective of whether all of the members are living, or some of the members are living and others are deceased. The bond network is defined herein as a group of humans having one or more bond associations (e.g., familial, social, work, financial, sports, etc.) that tie their interactions together in a unique way that identifies the members based on those bond associations. For example, a human may be part of a family-based bond network, and that human's baseline personality may be adjusted when interacting with other family members. That human may use certain language, a certain tone of voice, and certain overall mannerisms when speaking with other family members as opposed to when speaking with people outside of his or her family-based bond network. As another example, that same human may be part of a work-based bond network, and may interact quite differently with his or her co-workers than his or her family members. In other words, the bond network in which the human is a member identifies that human's personality for purposes of that particular bond network, and that human's personality may be quite different when communicating with members of a different bond network.

In one embodiment, the bond network is a finite, exclusive network of members. In other words, the bond network is not an open network of interactions between the human and any user, which would lead to significant noise while performing data analytics. For instance, the bond network may have a predetermined maximum number of members. By limiting the number of members permitted, the bond network is able to analyze interactions between members on a granular level to optimally identify personalities of those members within a particular social dynamic. For example, a family-based bond network may be limited in size to only ten members, thereby confining interactions, which are analyzed, to immediate family members. (Ten is provided only as an example. The bond network may be limited to a different quantity that allows for optimal assessment of interactions within a bond network. The finite quantity may vary based upon the particular context (e.g., a family-based bond network may be different in size than a work-based bond network, depending upon the particular size of a human's family and workforce).) Accordingly, a bond-network specific processor (i.e., a computer-implemented processor specifically configured to analyze text-based messages, audio communications, and/or video communications between members of a bond network) may analyze those family-based interactions to identify not only how the human interacts, on a granular level, amongst family members, but also on a sub-granular level amongst sub-groups within that bond network. For example, a human may be identified by the bond-specific processor as having a relaxed demeanor within the family-based bond network, as opposed to a more nervous demeanor in general. Furthermore, the bond-specific processor may determine that the human expresses that relaxed demeanor in different ways within various subset member groups of the bond network. For example, the human may utilize various vocabulary indicative of being relaxed with his or her siblings, and quite different vocabulary with his or her parents.

By identifying the personality of a human user based on interactions within the bond network during the life of the human, a neural network engine may then simulate those interactions posthumously. For example, a messaging configuration (e.g., a messaging app) may allow users within the bond network to communicate amongst each other during the lives of the human users. Even after the death of one of the members of the bond network, the bond-specific processor allows for continuous, posthumous communication by interacting with a neural network engine that simulates the interactions with various subset member groups of the bond network. By modifying a baseline persona, of the human, obtained from external sources to match interactions between the human and a particular member subset group of the bond network, a computer-implemented bond network platform is able to perform such posthumous simulation. The aforementioned granular and sub-granular analyses allow for such continuous interaction via posthumous simulation such that live human users within the bond network may have realistic communications with the posthumous simulation of the human persona. To accomplish that effect, the bond network-specific processor, or other processor described herein, may assess whether the posthumous simulation meets a predetermined realism threshold (e.g., eighty percent of the time a live user recognizes the communication from the posthumous virtual simulation as being real), and further modify the posthumous simulation to meet that threshold if not met. (Eighty percent is provided only as an example. Other percentages may be utilized for the predetermined realism threshold. Having a predetermined realism threshold of less than one hundred percent is optimal because even live users will at times interact differently, and in unexpected ways, from that which is considered the norm for that user.) The bond network-specific processor may quantify realism by monitoring user feedback during the interactions with the posthumous, virtual simulation of the member of the bond network, and tallying interactions that are considered realistic or unrealistic. For example, if a live human user responds with feedback indicative of bewilderment (e.g., “huh,” “you sound different today,” etc.), the bond network-specific processor may assess that interaction as unrealistic.

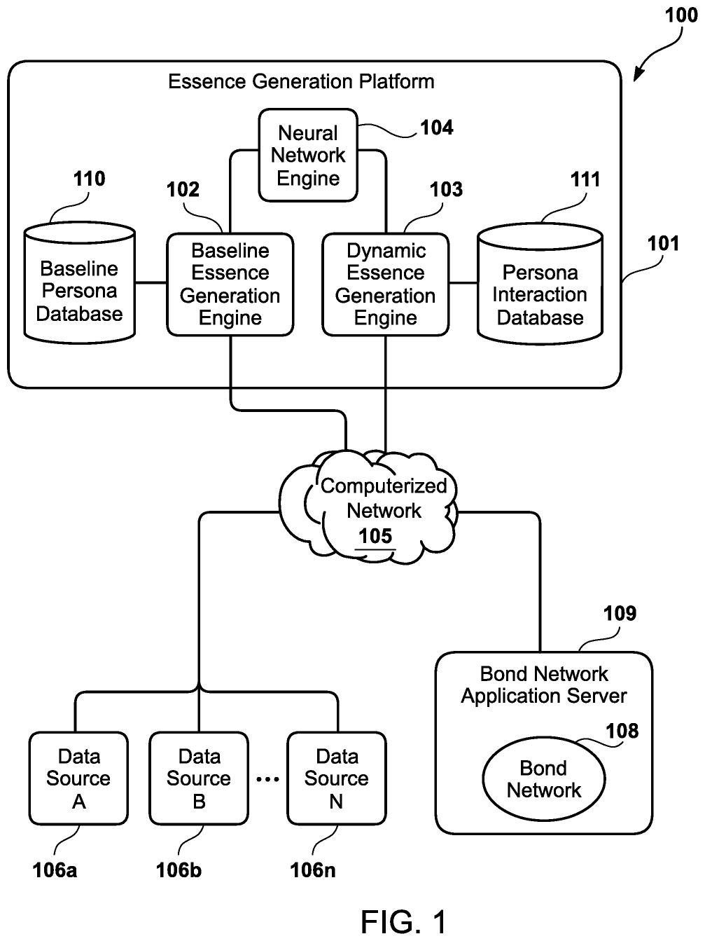

FIG. 1 illustrates a computer-implemented bond network system 100 that may be utilized to operate a software configuration that facilitates communication between members of a bond network 108 while all of the members are alive, as well as posthumous simulations of personas of bond network members after they are deceased. Accordingly, the computer-implemented bond network system 100 determines a baseline persona for a bond network member, and modifies that baseline persona during a posthumous simulation based on interactions during the life of the member of the bond network, As a result, the bond network software configuration (e.g., text-based messaging app, audio-based communication app, or video-based conferencing app) provides a seamless transition for live members of the bond network to be able to communicate in a realistic manner with a virtual simulation of the persona of the deceased member of the bond network 108.

In one embodiment, the computer-implemented bond network system 100 has a bond network application server 109 that implements a computer-accessible interface for the bond network 108 via a software app. Accordingly, even while all of the members of the bond network 108 are living, the bond network application server 109 allows all of those members to communicate with each other individually, or with subset member groups (e.g., three other members of a ten member bond network), of the bond network. Subsequent to death, or physical incapacitation, of a member of the bond network, the network application server 109 continues to operate the software app by inserting a simulated persona in place of the deceased or incapacitated member of the bond network 108. The virtual persona may simulate the personality of the deceased or incapacitated member via similar mannerisms (e.g., type of interjections, response speed, types of emojis utilized, tone of voice, laugh frequency, grunt frequency, hand gesture frequency, etc.) via various communication modalities (e.g., text-based communications, audio-based communications, and/or video-based communications). Various imagery and/or audio corresponding to the deceased or incapacitated bond network member may be utilized by the software app to provide an additional sense of realism.

Additionally, the computer-implemented bond network system 100 has a computer-implemented essence generation platform 101 that may be utilized to capture data from a human member of the bond network 108 during his or her life. In particular, the computer-implemented essence generation platform 101 may have a baseline essence generation engine 102 that is utilized to capture baseline data regarding both core personality characteristics and specific interaction-based characteristics during the life of the affected bond network member. (Alternatively, some, if not all, of the interaction-based characteristics may be determined posthumously by performing an analysis on previous interactions between the affected bond network member and a particular, distinct living bond network member.) The baseline data is captured by receiving data from various data sources 106a-n, possibly through a computerized network 105. Furthermore, the baseline data may be stored in a baseline persona database 110 for subsequent retrieval. The data sources 106a-n may include computing devices (e.g., personal computer, laptop, smartphone, tablet device, smartwatch, smart wearables, etc.) that the bond network member utilizes to take personality assessments, communicate with other humans inside or outside of the bond network 108, take notes, store videos, store images, and the like. The baseline data may be based on core characteristics, which are characteristics that form a basis for the persona of the human, independent of specific interactions with other human users, and/or interaction data with other humans. Amongst a myriad of possible examples, core characteristics may include certain phrases, tone of voice, ranges for response times, etc. that form a universal common denominator for the human user amongst interactions with a significant number (i.e., exceeding a predetermined threshold) of people. In one embodiment, the core characteristics are determined on a global scale (e.g., outside of the bond network) to determine a baseline persona of the affected bond network member that is modified to match the particular bond network 108. In another embodiment, the core characteristics are determined specific to the bond network 108 for interactions with all, or most of, the members of the bond network 108 to determine a baseline persona for the bond network 108 that is modified on a sub-granular level to match a particular member subgroup within the bond network 108. As yet another alternative, both of the foregoing possibilities are considered for formulating the baseline persona.

Based on the baseline data stored in the baseline persona database 110, a neural network engine 104 posthumously (or during physical incapacitation) simulates the virtual persona of the affected member of the bond network 108 during a virtual interaction between other members of the bond network 108 and a virtual representation of the affected member.

Furthermore, a dynamic essence generation engine 103 may receive interaction data between the affected bond network member and other members, during the life of the affected bond network member (or based on a subsequent review of data stored via the software app) from the bond network application server 109 via the computerized network 105; that persona interaction data may then be stored by a persona interaction database 111 for subsequent retrieval. For instance, the dynamic essence generation engine 103 may utilize the persona interaction data for a particular bond network 108 to retrain the neural network engine 104 to modify the baseline virtual persona based on that particular bond network 108. Accordingly, the virtual persona for the affected bond member will be simulated not only on baseline data particular to his or her core characteristics, but also the makeup of the particular bond network 108, and the interactions associated therewith.

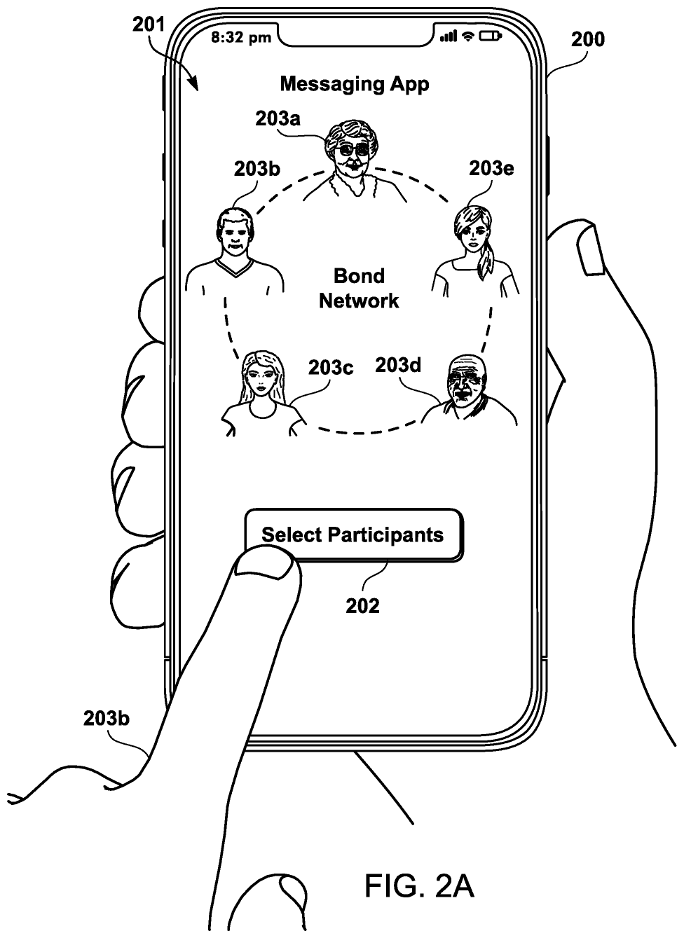

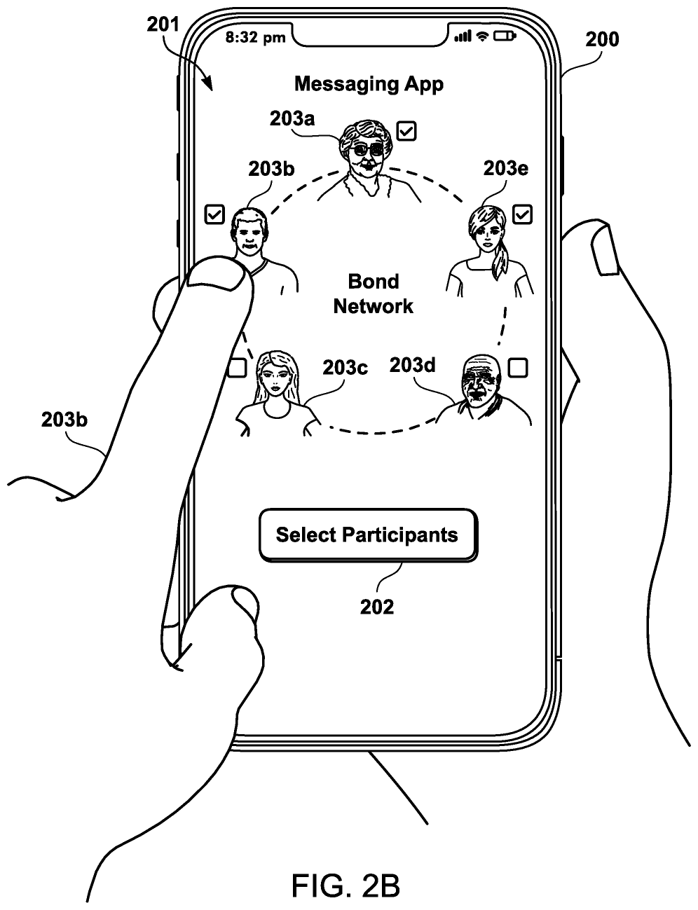

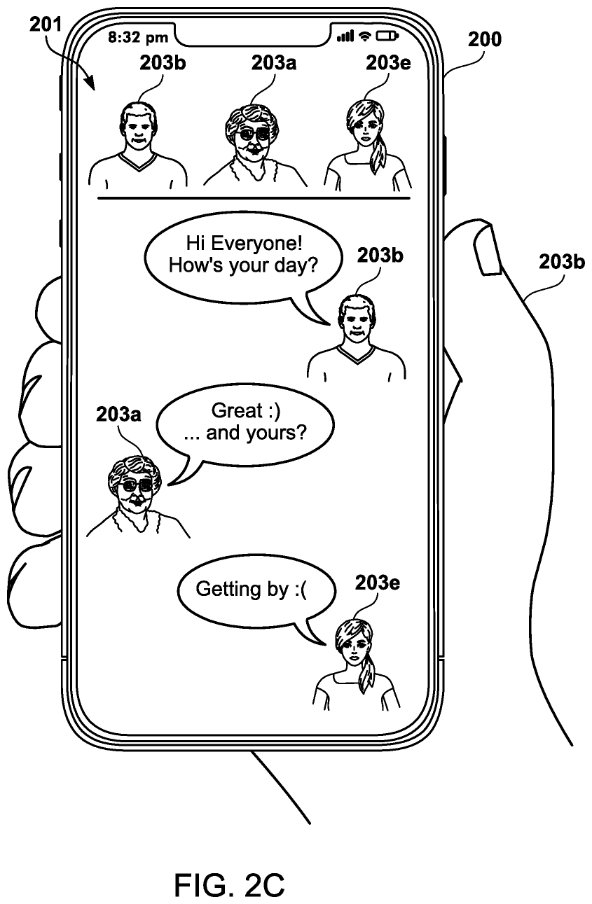

FIGS. 2A-2D illustrate examples of a bond network user interface 201 rendered by a computing device 200. As an example, FIG. 2A illustrates a smartphone 200 operated by a user 203b to invoke a messaging app to communicate with other bond network members. In one embodiment, the bond network user interface 201 illustrates imagery (e.g., bond network member avatars 203a-e) associated with the bond network 108. The user 203b may then select an indicium 202 (e.g., button) to initiate selection of particular members of the bond network 108 to communicate with. The bond network user interface 201 may display imagery of the bond network members, irrespective of whether they are living, incapacitated, or deceased. Accordingly, the bond network user interface 201 improves the usability of the computing device 200 to allow bond network members to seamlessly communicate with other bond network members. For instance, an active (living) member in the bond network 108 may indicate the status of the affected member as inactive (incapacitated or deceased). The bond network application server 109 may then seamlessly transition to participation by the virtual representation of the affected bond network member.

FIG. 2B illustrates the user 203b selecting a subset member group from the bond network user interface 201. As an example, the user 203b may provide one or more user inputs (e.g., touch-based inputs) to indicate which bond network members are present in a subset group communication (e.g., group chat, group video conference, etc.). In one embodiment, various visual feedback (e.g., checkboxes, highlighting, etc.) may be utilized to indicate the user selections. For the purpose of the example, FIG. 2B illustrates the bond network members 203a, 203b, and 203e being selected as a subset for the bond network communication. FIG. 2C illustrates an example of a text-based group subset communication between the bond network members 203a, 203b, and 203e selected via the bond network user interface 201. Furthermore, FIG. 2D illustrates an example of a video-based group subset communication between the bond network members 203a, 203b, and 203e selected via the bond network user interface 201.

Although the bond network interface 201 is illustrated for user selection of subset member groups, alternatively, the bond network specific processor may automatically recommend or select the subset member group for a user.

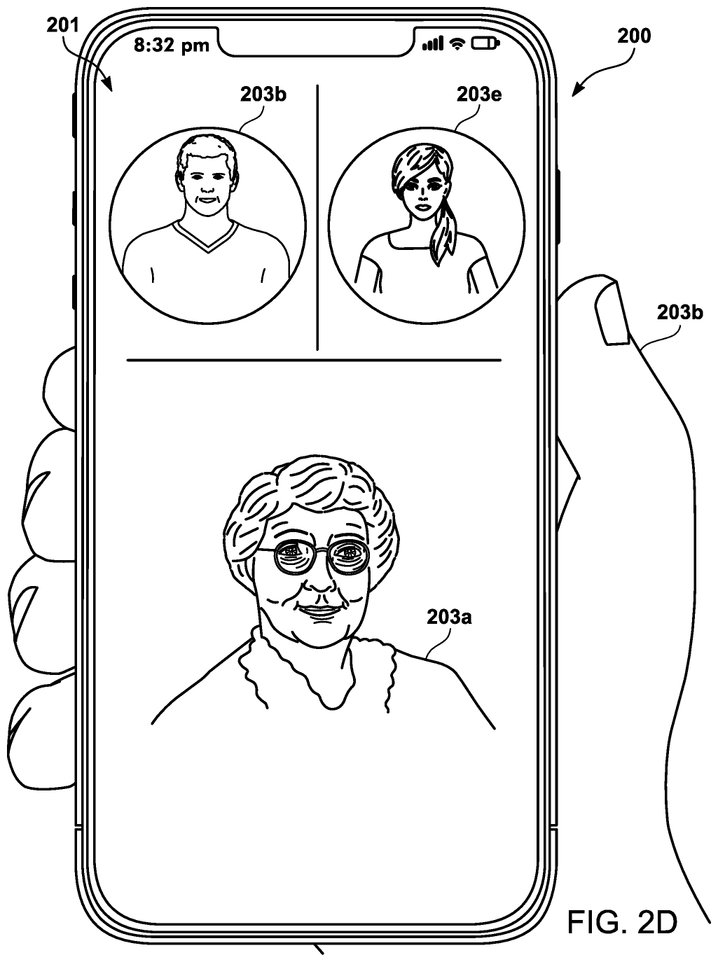

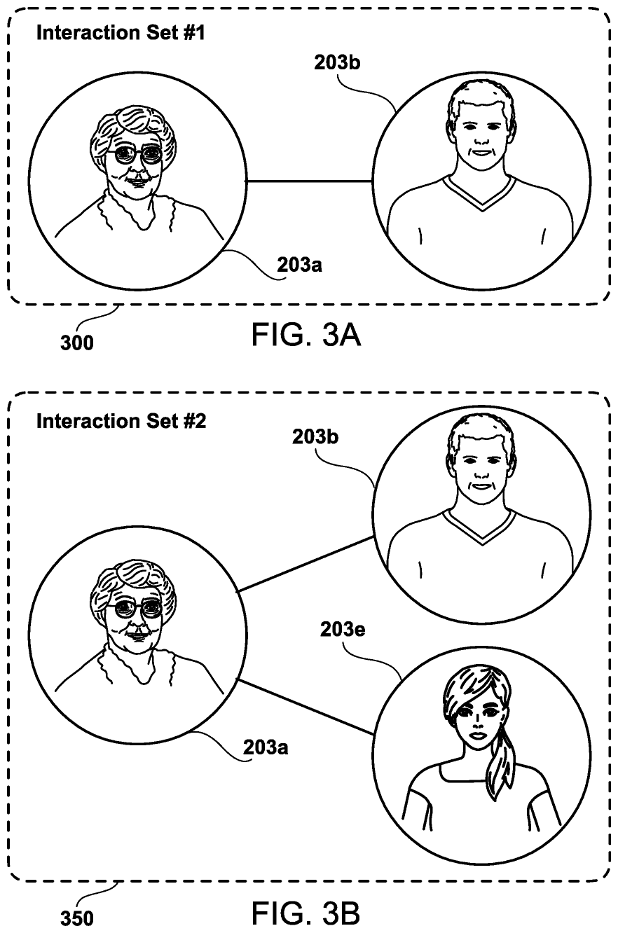

The bond network interface 201 illustrated in FIGS. 2A-2D allows for a variety of different interactions, namely the affected bond network member with each potential subgroup within the bond network 108. For example, FIGS. 3A and 3B illustrate some possible interaction data sets that may be utilized to dynamically retrain the neural network engine 104, illustrated in FIG. 1, based on the makeup of the particular subset member group that is selected via the bond network user interface 201, illustrated in FIGS. 2A-2D. In particular, FIG. 3A illustrates an interaction data set 300 that includes the bond network member 203a, the affected member, and only one other bond network member 203b. FIG. 3B illustrates an interaction data set 350 that includes the bond network member 203a, the affected member, and two other bond network members 203b and 203e. (Various other subset member groups may be utilized; the foregoing interaction data sets are provided only as examples.) The different interaction data sets allow the dynamic essence generation engine 103 to retrain the neural network engine 104 on a member subgroup by member subgroup basis to modify the baseline persona of the affected member 203a to specifically match the mannerisms that identify that affected member's persona for that member subgroup.

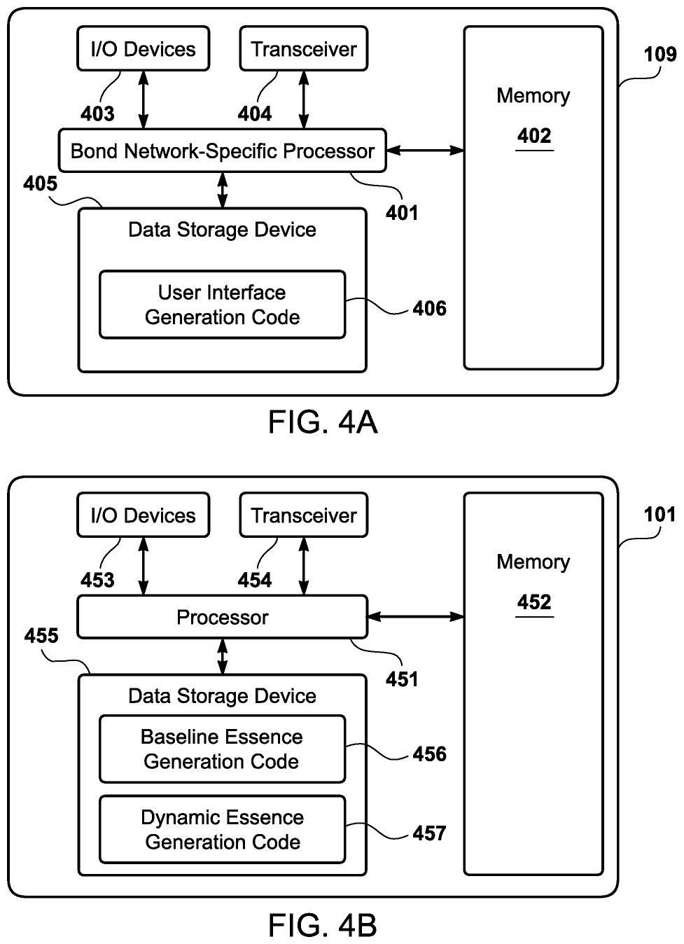

FIG. 4A illustrates a system configuration for the bond network application server 109, illustrated in FIG. 1. The bond network application server 109 may have a bond network-specific processor 401, which may be specialized for generating a user interface to automatically transition from an active user to a virtual simulation for an inactive user for participation in a group communication software configuration, such as a software app. Accordingly, the bond network-specific processor 301 may be utilized to generate the user interface 201 illustrated in FIGS. 2A-2D.

The system configuration may also include a memory device 402, which may temporarily store interaction data, such as the interaction data sets 300 and 350 illustrated in FIGS. 3A and 3B. The bond network application server 109 may then transmit the interaction data to the essence generation platform 101 so that the dynamic essence generation engine 103 may modify the baseline persona model of the affected member to retrain the neural network engine 104. As a result, the bond network-specific processor 401 is able to render an indistinguishable, or almost indistinguishable, virtual representation of the affected member.

Furthermore, the memory device 402 may store computer readable instructions performed by the bond network-specific processor 401. As an example of such computer readable instructions, a data storage device 405 within the system configuration may store user interface generation code 406. The bond network-specific processor 401 may execute the user interface generation code 406 to generate the bond network user interface 201, illustrated in FIGS. 2A-2D.

Finally, the system configuration may have one or more input/output (“I/O”) devices 403 that may receive inputs and provide outputs. Various devices (e.g., keyboard, microphone, mouse, pointing device, hand controller, joystick, display device, holographic projector, etc.) may be used for the I/O devices 403. The system configuration may also have a transceiver 404 to send and receive data. Alternatively, a separate transmitter and receiver may be used instead.

FIG. 4B illustrates a system configuration for the essence generation platform 101 illustrated in FIG. 1. The essence generation platform 101 may have a processor 451, which may be specialized for data capture and machine learning. Accordingly, the processor 351 may be used to perform the operations illustrated in FIG. 1 for generating an essence for a virtual persona of the affected network bond member for posthumous virtual simulation via one or output modalities.

The system configuration may also include a memory device 452, which may temporarily store data structures, or portions thereof, to improve processing time for the processor 451. For example, the memory device 452 may store a baseline persona model from the baseline persona database 110 and an interaction persona model from the persona interactions database 111, which may be utilized by the processor 451 to train or retrain, respectively, the neural network engine 104 with improved processing times. For example, the processor 451 may need to further modify the virtual persona during a live, real-time interaction because the realism tolerance threshold is not met according to living members providing feedback (e.g., multiple “huhs”). To salvage the realism of the communication, the processor 451 may have to dynamically retrain the neural network engine 104 to make adjustments on-the-fly, in real-time (i.e., imperceptible time delay measured from user feedback) or substantial real-time (i.e., perceptible, but acceptable in the particular communication context, time delay).

Furthermore, the memory device 452 may store computer readable instructions performed by the processor 451. As an example of such computer readable instructions, a data storage device 455 within the system configuration may store baseline essence generation code 456 and dynamic essence generation code 357. The processor 451 may execute the baseline essence generation code 456 to generate and operate the baseline essence generation engine 102, and the dynamic essence generation code 457 to generate and operate the dynamic essence generation engine 103, illustrated in FIG. 1.

Finally, the system configuration may have one or more input/output (“I/O”) devices 453 that may receive inputs and provide outputs. Various devices (e.g., keyboard, microphone, mouse, pointing device, hand controller, joystick, display device, holographic projector, etc.) may be used for the I/O devices 453. The system configuration may also have a transceiver 454 to send and receive data. Alternatively, a separate transmitter and receiver may be used instead.

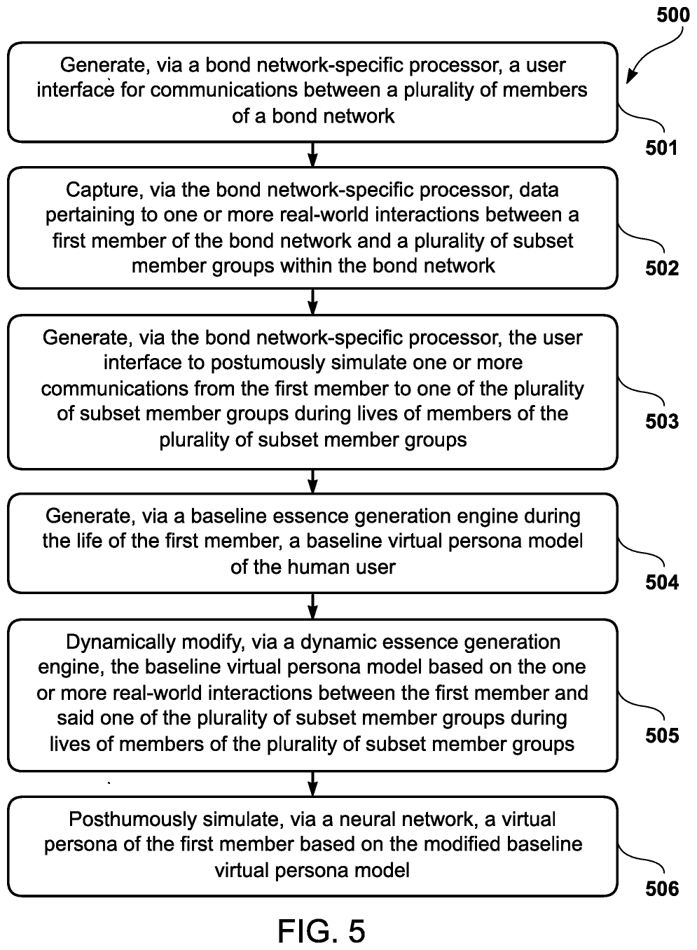

FIG. 5 illustrates a computer-implemented process 500 that may be utilized to generate a bond network for posthumous persona simulation. At a process block 501, the computer-implemented process 500 generates, via a bond network-specific processor 401, a user interface for communications between a plurality of members of a bond network 108. Furthermore, at a process block 502, the process 500 captures, via the bond network-specific processor 401, data pertaining to one or more real-world interactions between a first member of the bond network and a plurality of subset member groups within the bond network 108. Additionally, at a process block 503, the process 500 generates, via the bond network-specific processor 401, the user interface to posthumously simulate one or more communications from the first member to one of the plurality of subset member groups during lives of members of the plurality of subset member groups. At a process block 504, the process 500 generates, via a baseline essence generation engine 102 during a life of the first member, a baseline virtual persona model of the human user. Moreover, at a process block 505, the process 500 dynamically modify, via a dynamic essence generation engine, the baseline virtual persona model based on the one or more real-world interactions between the first member and said one of the plurality of subset member groups during lives of members of the plurality of subset member groups. Finally, at a process block 506, the process 500 posthumously simulates, via a neural network, a virtual persona of the first member based on the modified baseline virtual persona model.

Although only one affected member of the bond network 108 is described as interacting with remaining live members of the bond network 108, multiple affected members may have associated virtual representations that are present within the bond network 108. As a result, a virtual representation may simulate not only a posthumous (or incapacitated) interaction with a live bond network member, but also with a different virtual representation corresponding to another affected bond network member.

It is understood that the processes, systems, apparatuses, and computer program products described herein may also be applied in other types of processes, systems, apparatuses, and computer program products. Those skilled in the art will appreciate that the various adaptations and modifications of the embodiments of the processes, systems, apparatuses, and computer program products described herein may be configured without departing from the scope and spirit of the present processes and systems. Therefore, it is to be understood that, within the scope of the appended claims, the present processes, systems, apparatuses, and computer program products may be practiced other than as specifically described herein.

1. A computer-implemented bond network platform comprising:
a processor;
a bond network application server that generates, via a bond network-specific processor, a user interface for communications between a plurality of members of the bond network, captures, via the bond network-specific processor, data pertaining to one or more real-world interactions between a first member of the bond network and a plurality of subset member groups within the bond network, and generates, via the bond network-specific processor, the user interface to (i) perform ante-mortem rendering, during a life of the first member, of one or more communications from the first member to one of the plurality of subset member groups during lives of members of the plurality of subset member groups and (ii) transition to posthumous simulation of newly created communications from the first member to said one of the plurality of subset member groups during said lives of members of the plurality of subset member groups and after the first member is deceased, the user interface displaying a plurality of member images from which said one of the plurality of subset member groups is selected by a member, other than the first member, in the plurality of members that interacts with the user interface during both the ante-mortem rendering and the posthumous simulation, the plurality of images including (i) an image of the first member and (ii) images of at least two members other than the first member, wherein the bond network comprises a predetermined maximum number of members, wherein the predetermined maximum is selected from a plurality of different maximums based on a context associated with the bond network; and
an essence generation platform that generates, via a baseline essence generation engine during a life of the first member based on one or more communications between the first member and one or more other members of the plurality of subset member groups during the life of the first member, a baseline virtual persona model of the first member, dynamically modifies, via a dynamic essence generation engine, the baseline virtual persona model based on the one or more one or more real-world interactions between the first member and said one of the plurality of subset member groups during lives of members of the plurality of subset member groups, and posthumously simulates, via a neural network, a virtual persona of the first member, based on the modified baseline virtual persona model, for interaction with the other members in said one of the plurality of subset member groups, the one or more real-world interactions between the first member and said one of the plurality of subset member groups being distinct from one or more additional interactions between the first member and members in subset member groups other than said one of the plurality of subset member groups, wherein the modification to the baseline virtual persona model is performed by automatically removing one or more persona attributes from the baseline virtual persona model that are inconsistent with said one or more real-world interactions between the first member and said one of the plurality of subset member groups during lives of members of the plurality of subset member groups, wherein the modification to the baseline virtual persona model is performed by automatically adding one or more persona attributes from the baseline virtual persona model that are consistent with said one or more real-world interactions between the first member and said one of the plurality of subset member groups during lives of members of the plurality of subset member groups.

2. (canceled)

3. The computer-implemented bond network platform of claim 1, wherein the bond network comprises a plurality of bond associations amongst the plurality of members.

4. The computer-implemented bond network platform of claim 1, wherein the baseline essence generation engine generates the baseline virtual persona model based on a personality assessment of the first member performed during the life of the first member.

5. The computer-implemented bond network platform of claim 1, wherein the baseline essence generation engine generates the baseline virtual persona model based on one or more communications between the first member and one or more non-members of the bond network during the life of the first member.

6. (canceled)

7. (canceled)

8. (canceled)

9. The computer-implemented bond network platform of claim 1, wherein the user interface is text-based.

10. The computer-implemented bond network platform of claim 1, wherein the user interface is audio-based.

11. The computer-implemented bond network platform of claim 1, wherein the user interface is video-based.

12. (canceled)

13. A computer program product comprising a non-transitory computer useable storage device having a computer readable program, wherein the computer readable program when executed on a server computer causes the server computer to:
generates, via a bond network-specific processor, a user interface for communications between a plurality of members of a bond network, wherein the predetermined maximum is selected from a plurality of different maximums based on a context associated with the bond network;
capture, via the bond network-specific processor, data pertaining to one or more real-world interactions between a first member of the bond network and a plurality of subset member groups within the bond network;
perform, via the bond network-specific processor at the graphical user interface during a life the first member, ante-mortem rendering of one or more communications from the first member to one of the plurality of subset member groups during lives of members of the plurality of subset member groups;
transition, via the bond network-specific processor at the graphical user interface, to posthumous simulation of newly created communications from the first member to said one of the plurality of subset member groups during said lives of members of the plurality of subset member groups and after the first member is deceased;
generate, via a baseline essence generation engine during a life of the first member, a baseline virtual persona model of the first member based on one or more communications between the first member and one or more other members of the plurality of subset member groups during the life of the first member;
dynamically modify, via a dynamic essence generation engine, the baseline virtual persona model based on the one or more real-world interactions between the first member and said one of the plurality of subset member groups during lives of members of the plurality of subset member groups; and
posthumously simulate, via a neural network, a virtual persona of the first member, based on the modified baseline virtual persona model, for interaction with the other members in said one of the plurality of subset member groups, the one or more real-world interactions between the first member and said one of the plurality of subset member groups being distinct from one or more additional interactions between the first member and members in subset member groups other than said one of the plurality of subset member groups, wherein the modification to the baseline virtual persona model is performed by automatically removing one or more persona attributes from the baseline virtual persona model that are inconsistent with said one or more real-world interactions between the first member and said one of the plurality of subset member groups during lives of members of the plurality of subset member groups, wherein the modification to the baseline virtual persona model is performed by automatically adding one or more persona attributes from the baseline virtual persona model that are consistent with said one or more real-world interactions between the first member and said one of the plurality of subset member groups during lives of members of the plurality of subset member groups.

14. (canceled)

15. The computer program product of claim 13, wherein the bond network comprises a plurality of bond associations amongst the plurality of members.

16. The computer program product of claim 13, wherein the baseline essence generation engine generates the baseline virtual persona model based on a personality assessment of the first member performed during the life of the first member.

17. The computer program product of claim 13, wherein the baseline essence generation engine generates the baseline virtual persona model based on one or more communications between the first member and one or more non-members of the bond network during the life of the first member.

18. (canceled)

19. (canceled)

20. (canceled)
